(19) United States
(12) Patent Application Publication
(10) Pub. No.: US 2002/0117938 A1
(43) Pub. Date: Aug. 29, 2002

(54) Parametric wave amplifier using plate modes

(76) Inventors: John Stuart Foster, Santa Barbara, CA (US); Richard Thomas Martin, Goleta, CA (US)

Correspondence Address: John S. Foster, Innovative Micro Technology, 75 Robin Hill Road, Goleta, CA, 93117, US

(21) Appl. No.: 09/797,643

(22) Filed: Feb. 27, 2001

(51) Int. Cl. H01L 41/04

(52) U.S. Cl. 310/313 D; 310/313 R

(57) ABSTRACT

The present invention describes a parametric amplifier, which uses transverse plate modes of a mechanically elastic material as the nonlinear medium for the amplification. The device may be rendered as a filter, amplifier, oscillator or mixer, and multiple devices may be constructed in a small physical space using MEMS and photolithographic technologies. Because mechanical modes are used rather than acousto-electric interactions with a semiconductor, the parametric amplifier disclosed herein is more robust against severe environmental conditions such as temperature and ambient EM radiation.

### FIELD OF THE INVENTION

This invention relates to the parametric amplification of plate waves.

### BACKGROUND OF THE INVENTION

Previously described acoustic wave amplifiers make use of an acousto-electric interaction, in which traveling electric fields, generated by acoustic waves in a piezoelectric material, produce a spatial density oscillation of charge carriers in an adjacent semiconducting material. Acoustic waves have found application as passive delay lines and signal processors, where their relatively slow velocity, about 10⁻⁵ times that of electromagnetic velocity, permits relatively long electric signal delay times in a relatively small physical space. While devices may be made using both bulk mode propagation as well as surface propagation, the latter has found wider utility because of the accessibility of intermediate points along the propagation path for structure shaping and tapping.

A typical surface acoustic wave (SAW) transducer comprises a pair of interdigitated electrodes deposited on the surface of a piezoelectric material, with adjacent fingers of the electrodes spaced by one half wavelength of the transducer design frequency. One such pair may launch the acoustic wave in the piezoelectric film, and another similar pair may form a detector, which outputs a radio frequency (rf) signal in response to the detected wave.

A third electrode may be deposited on top of the semiconductor layer, and serves to tune the drift velocity of charge carriers by applying a bias voltage to the layer. The magnitude and direction of the applied electric field determines the properties of the dispersion curve of the device. The top electrode, semiconductor, insulator, and piezoelectric film with input and output transducers, comprise a general purpose acoustic wave modulator.

Amplifiers may be constructed from the basic SAW transducer, by applying the semiconductor material in the propagation path of traveling waves on the piezoelectric material, such that the surface signal wave and the propagating (pumping) wave are substantially collinear through some portion of the piezoelectric material. Again the space capacitance nonlinearity in the adjacent semiconductor material provides amplification of the surface signal.

SAW's are used extensively in industry for narrow bandpass filters, for example as the front-end filter of a cell phone, and the tuning device on a television. SAW devices acting as a filter are generally very lossy, and may attenuate the signal frequency by more than 90%. Therefore amplifiers are typically needed after filtering, but separate, serial devices are expensive and awkward.

In addition, a “mixer”, which up-converts or down-converts the signal frequency, is often required in communications and signal processing, for example, radio transmission and reception. A typical scenario is one in which a signal is up-converted by mixing the signal with a fixed oscillator, to a carrier band for transmission. Upon reception the carrier frequency is removed by down-conversion to restore the original signal.

Parametric amplification is a well-understood phenomenon which may be demonstrated in many different nonlinear systems. A signal is amplified parametrically by interaction of a signal wave at frequency wₛ with a pump wave at frequency wₚ in a nonlinear material, to generate an output wave at frequency wₒ. For propagating waves, the conservation of energy requires that

wₒ=wₚ+wₛ

Conservation of momentum further requires that

kₒ=kₚ+kₛ

where kₒ, kₚ and kₛ are the respective wave vectors of the output, pump and signal waves. Adjustment of the angles between the three wave vectors will determine whether the signal wave is up-converted (wₒ=wₚ+wₛ) or down-converted (wₒ=wₚ−wₛ), in order to conserve momentum.

The applicability of SAW devices, filters, amplifiers and mixers, is limited in part by the cost of the materials. The piezoelectric substrate materials are relatively exotic and expensive materials, such as lithium niobate and lithium tantalate. Sensitivity of the device to temperature also limits their application under more extreme conditions. For example as temperatures are lowered, the response of the transducers decreases. Conversely, at elevated temperatures, the conduction band is flooded by charge carriers, and again at some limit the device will cease to function. Typical operating ranges for semiconductor devices is ⁻40 to 100° C. Saw devices are also subject to disruption by electromagnetic radiation, which promotes excess charge carriers into the conduction band.

Lastly, multiple devices are often needed even for a single application. For example in the case of radio transmission, the signal must typically be amplified after down-conversion, because of the loss resulting from the down-conversion process. Using discrete SAW devices as known in the prior art is awkward and expensive.

Therefore, a heretofore unresolved problem with SAW transducers are their fragility in hostile environments, lack of easy interconnectivity or integration, and expense of materials. The invention disclosed herein describes an improvement over the prior art, by using plate waves as the nonlinear propagation mode for a parametric amplifier. The behavior of plate waves is described in M. S. Weinberg, B. T. Cunningham, and C. W. Clapp, Journal of Microelectromechanical Systems, Vol. 9, No. 3, September 2000, pp. 370-379.

### BRIEF DESCRIPTION OF THE DRAWINGS

The present invention will be understood more fully from the following detailed description, and from the accompanying drawings, which however, should not be taken to limit the invention to the specific embodiments shown but are for explanation and understanding only.

FIG. 1a is a simplified diagram of a parametric amplifier, according to this invention. FIG. 1b is a simplified diagram of a resonator.

FIG. 2 is a simplified diagram showing the orientation of the components of the amplifier for performing down-conversion.

FIG. 3 is a simplified diagram showing the orientation of the components of the amplifier for performing up-conversion.

FIG. 4a is a simplified schematic of the cross section of the parametric amplifier. FIG. 4b is a simplified schematic of a parametric amplifier including voids.

FIG. 5 is a simplified diagram of a multiple bandpass filter.

FIG. 6 is a simplified diagram of an oscillator.

### DETAILED DESCRIPTION

In this invention, a plate wave transducer is described which uses transverse plate modes in a mechanically elastic material, to provide the nonlinear medium for parametric amplification. Transverse plate waves are waves in which the stiffness of the plate provides the restoring force to the displacement caused by the plate wave. Tension may also be used, and the choice depends upon the application and choice of materials. A key characteristic of transverse plate modes is that the dispersion curve is upward and parabolic with respect to frequency, and this characteristic makes plate waves suitable as the nonlinear medium for parametric amplification.

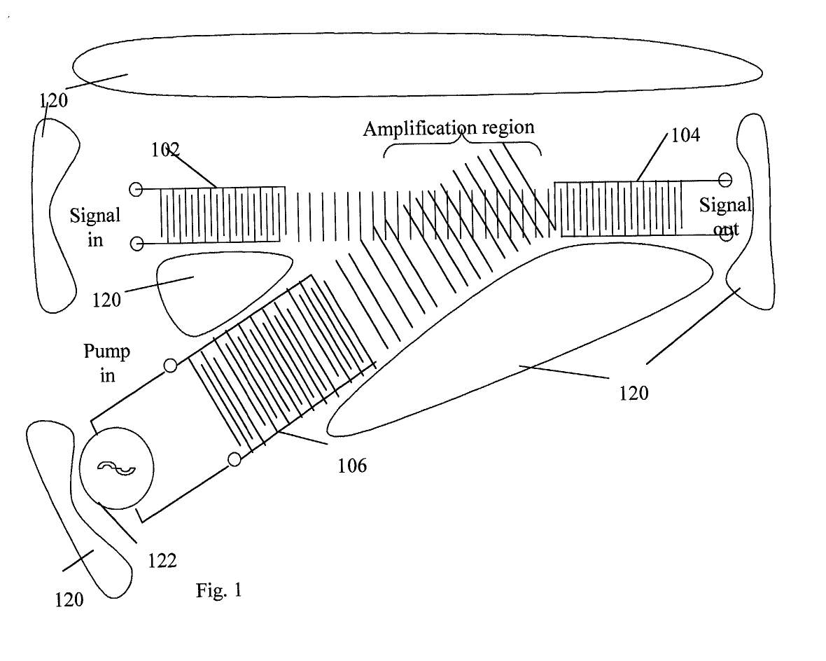

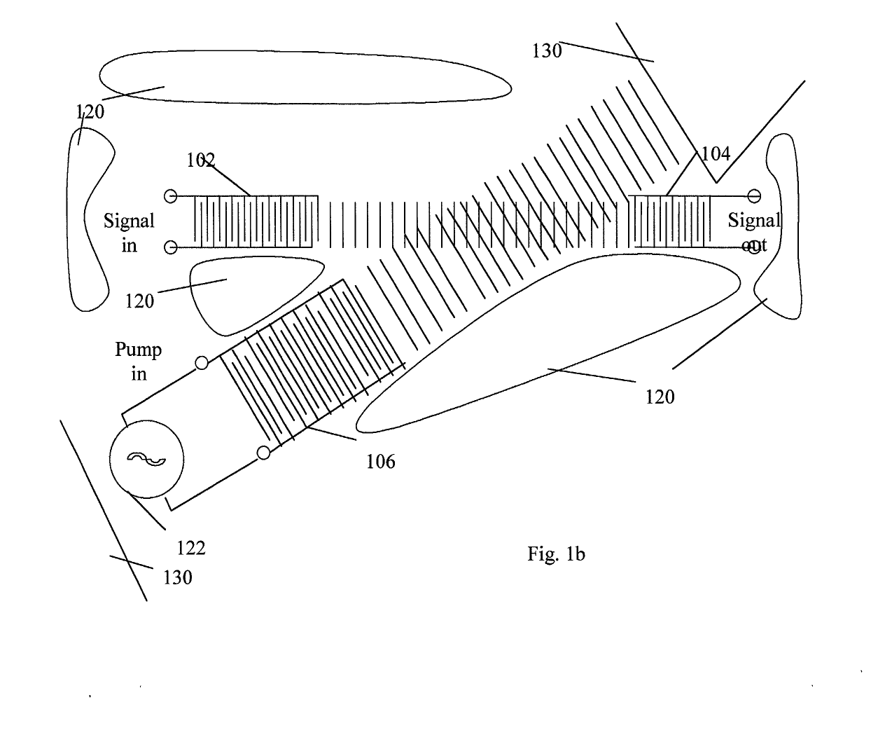

FIG. 1a is a simplified, top-down view of a device performing amplification of the input signal wave, according to this invention. The input electrical signal is converted to a plate mode with an acousto-electric transducer, and a pump wave is generated in the same fashion by exciting the pump transducer with an electrical oscillator. Input signal transducer 102 is made of electrically conductive fingers, which are interdigitated as shown, such that the spacing between fingers is one-half the wavelength of the plate mode. Pump transducer 106 is a similar set of interdigitated electrodes, but with a spacing appropriate for the pump wavelength. The pump transducer is driven by oscillator 122.

Each transducer launches a plate wave and in the overlapping region of the waves, the parametric amplification of the signal wave occurs. The amplified signal is converted into an electrical signal using output signal transducer 104. A number of damping bodies, labeled 120, serve to absorb acoustic energy in unwanted plate modes. Exemplary placement of these members is shown in the figure, although the specific shape and placement will depend on analysis of a given application.

FIG. 1b shows a device similar to that in FIG. 1a, but with reflecting elements 130 added to the pump wave at both ends of wave travel. Reflecting elements 130 define a resonant cavity, so that narrow bandwidth pump energy may be developed as a result of the Q-factor of the cavity. The reflection device may be as simple as an abrupt end of the plate, or a deposited film of sufficiently high impedance as to reflect the pump wave.

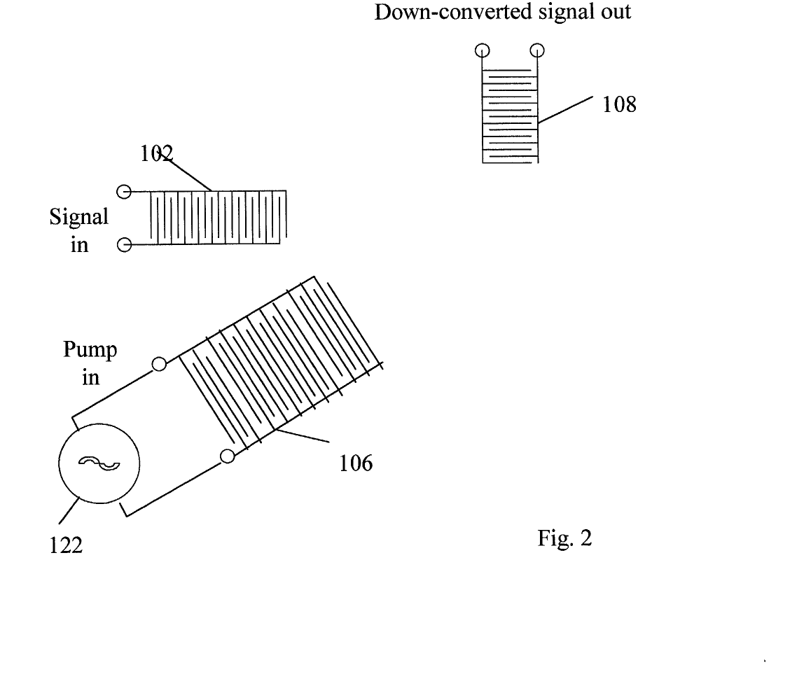

FIG. 2 shows a diagram of a device performing filtering, mixing and amplification. Signal transducer 102 and pump transducer 106 comprise the amplifier as described previously, and output transducer 108 is used to receive the output wave. The relative orientations of the signal, pump, and output transducers define a down-converting mixer, with output at the difference frequency wₒ=wₚ−wₛ. As before, pump transducer 106 is driven by oscillator 122.

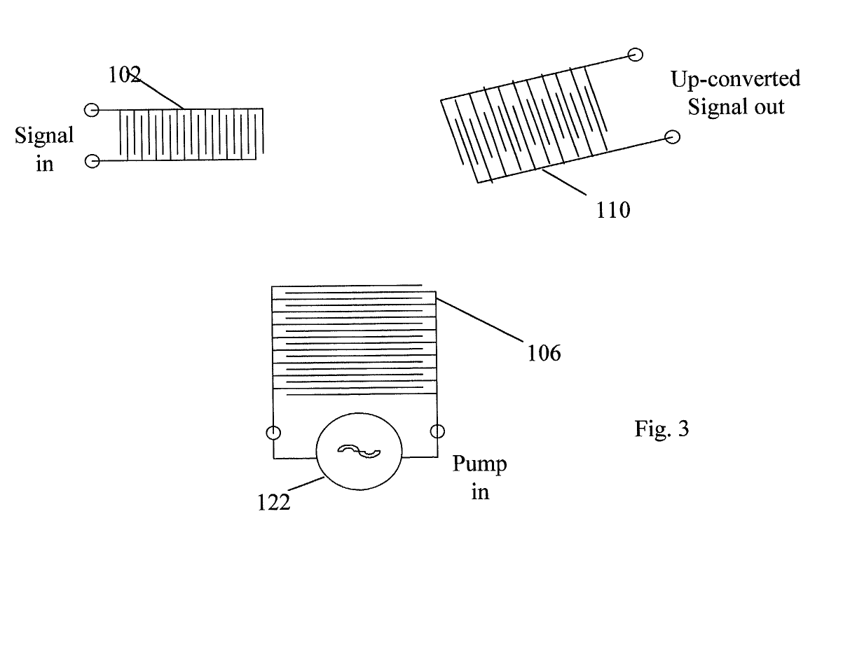

FIG. 3 shows a diagram of a device performing a frequency up-conversion using parametric amplification. Signal transducer 102 and pump transducer 106 produce the appropriate plate waves, and the relative orientations of the signal, pump, and output transducers define a up-converting mixer, with output at the sum frequency wₒ=wₚ+wₛ. As before, pump transducer 106 is driven by oscillator 122.

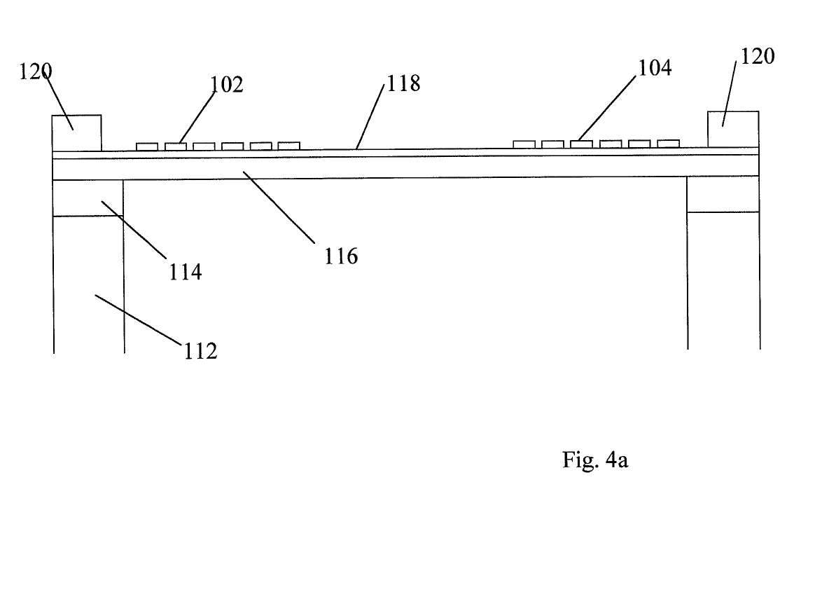

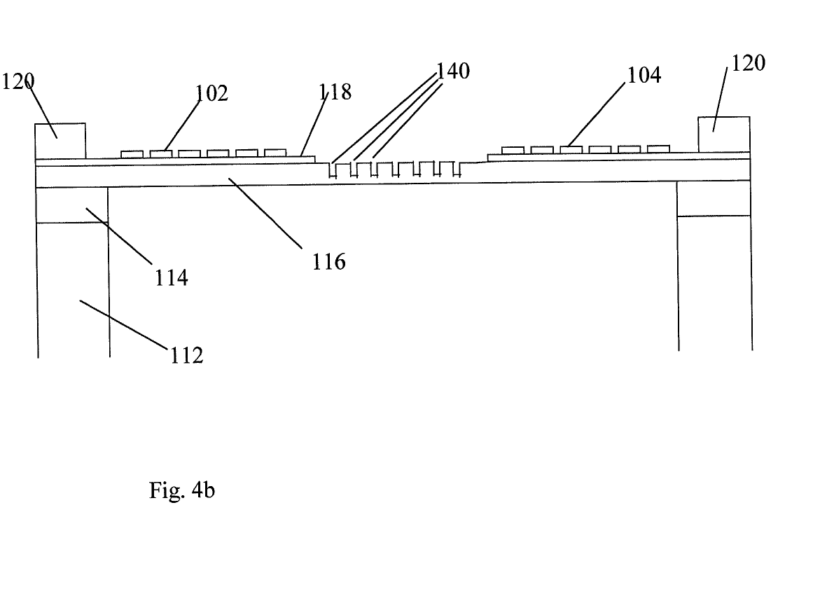

FIG. 4a shows a schematic of the cross-section of the plate and plate transducer. Substrate 112 supports insulator 114, which in turn supports plate 116. Plate 116 is the nonlinear medium supporting the transverse plate waves. Piezoelectric film 118 is attached to plate 116, as are input signal transducer 102 and output signal transducer 104. Pump transducer 106 is not shown in this figure for clarity. It is understood that the metallization layers which provide electrical access to signal tranducers 102, 104 and 106 are likewise attached to piezoelectric film 118, but not shown in the figure for clarity.

FIG. 4b shows a cross-section as in FIG. 4a, but with voids 140 formed in plate 116. These voids enhance the nonlinear interaction between the waves, and may be used to operate the device at lower powers. Other changes in plate 116 are also possible to perform a similar function to voids 140, including bumps on plate 116, which also break the symmetry of the plate and enhance the nonlinear interaction of the waves

Many different material choices are possible for the substrate 112, insulator 114 and absorbers 120. Substrate 112 may be of plastic, silicon, glass, aluminum, nickel, tungsten, silicon nitride, zinc oxide, aluminum nitride, quartz, germanium, gallium arsenide, or other suitable material with appropriate cost and durability properties. Insulator 114 is required if substrate 112 is not highly electrically resistive. Any of a number of insulating materials, such as silicon dioxide SiO₂, may be chosen. Plate 116 may also be a variety of materials, but in the current embodiment is silicon. Piezoelectric film 118 may be zinc oxide, lead zirconium titanate, aluminum nitride, lithium niobate, lithium tantalate, or other piezoelectric material. In the embodiment described here, the piezoelectric material is ZnO. Absorber 120 damps the plate waves of plate 116, and could be made of a variety of damping materials, for example a polymer such as photoresist.

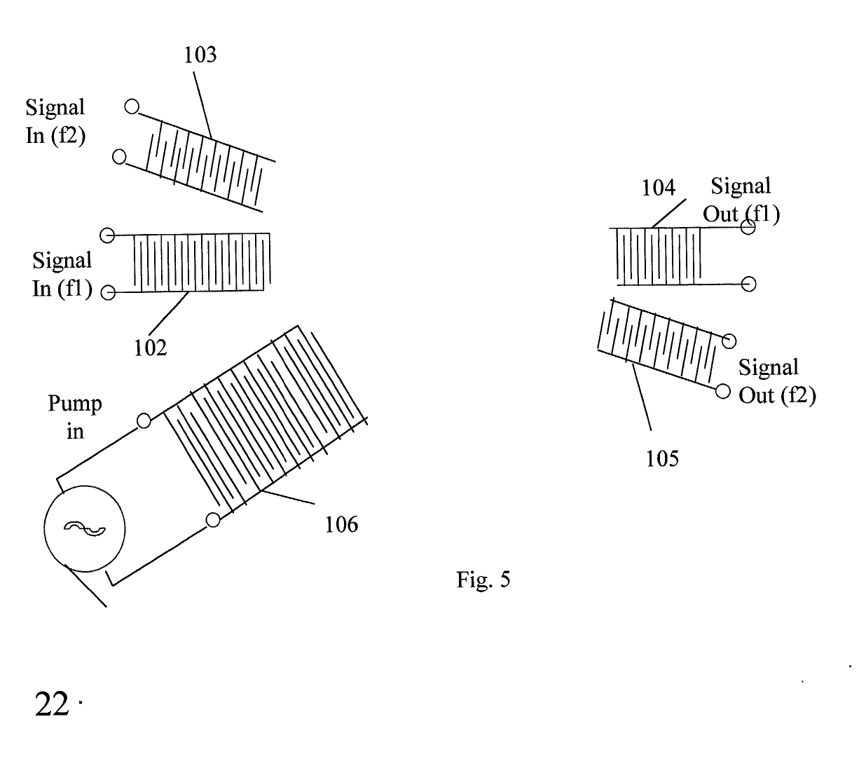

FIG. 5 shows an embodiment of a multiple bandpass filter and amplifier. There are two signal transducers as shown, signal transducer 102 for frequency f1 and signal transducer 103 for frequency f2. The signal transducers are placed at two different angles with respect to pump transducer 106, such that the signal frequencies intended for each signal transducer are resonant with the pump wave, i.e. the conditions of energy conservation and momentum conservation discussed previously are satisfied. This geometry allows for a single device to accommodate two separate bandpass frequencies. By adding more transducers, more bandpass channels may be accommodated. Accompanying each signal input transducer is a respective output transducer, shown in FIG. 5 as signal output transducers 104 and 105. The width of the bandpass filter may also be tuned by varying the amplitude of the pump wave. The higher the amplitude of the pump wave, the narrower the bandwidth of the amplified signal.

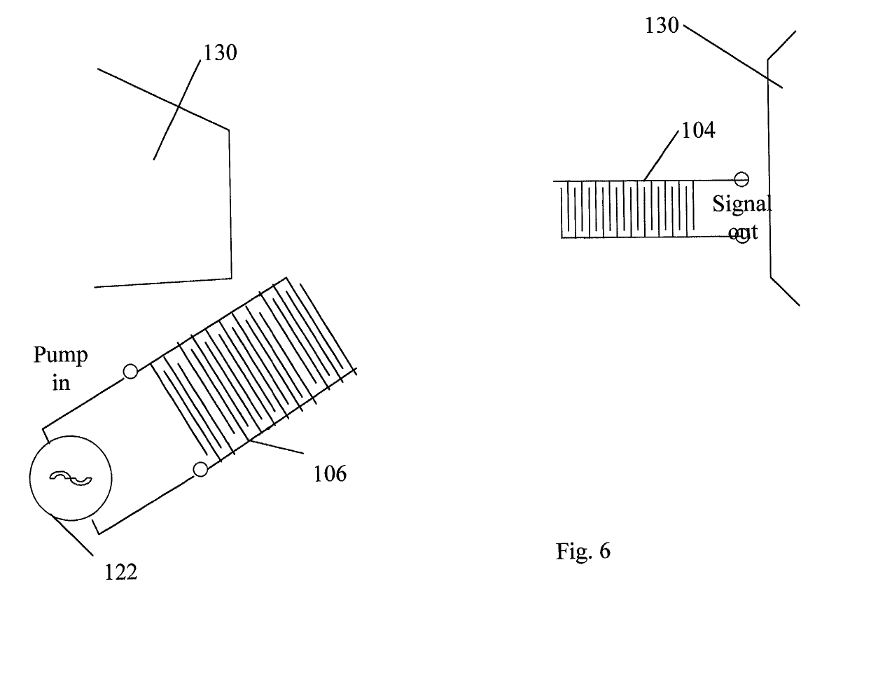

FIG. 6 shows an embodiment of an oscillator with high frequency stability. Reflection devices 130 are placed at both ends of the plate, and pump transducer 106 is driven by pump oscillator 122. The signal wave may either be introduced directly, or may be created from noise. It is amplified by the presence of the pump plate waves, and an output signal is generated at signal output transducer 104 which will have the property of very narrow bandwidth. In general, reflection devices 130 would be used at both ends of the plate for both the signal output waves as well as the pump waves, although this is not shown in FIG. 6 for simplicity.

While the embodiment of the parametric amplifier described herein uses a piezoelectric transducer to generate and receive plate waves, it is possible to use other means such as electrostatically-driven fingers, magnetically driven fingers, or thermal expansion fingers, and such devices, which are also known as actuators for micromachines. In addition, whereas we have cited the use of transverse plate modes, it is possible to alter the nature of the waves, for example by adding or subtracting tension on the plate, thereby fashioning a composition of plate waves and membrane behavior. In such cases, as long as the dispersion remains upward and the medium is nonlinear, the parametric effect will still exist and the spirit of this invention may be invoked. The pump transducer 106 is driven with oscillator 122, generating plate modes, which parametrically amplify the signal. The amplification of the signal (in the low gain regime) is exponential, given approximately by

Pₒᵤₜ=Pᵢₙ*exp(c*L)

in which Pᵢₙ is the input signal power, Pₒᵤₜ is the output signal power, c is a constant related to the power in the pump, and L is distance the signal and pump interact. In practice, the pump power may be adjusted to provide the desired gain in the amplifier.

The current invention may be implemented as low-noise signal amplifier, or a high-power amplifier, depending on the system requirements. In the high power application, the pump amplitude may be increased, and the pump/signal interaction length (L) may be increased. As the pump gives up significant energy to the signal, the signal amplitude may saturate while the pump energy depletes, and the system may be a very efficient amplifier of signal energy.

The bandwidth of the invention is determined by a combination of factors, including the length of plate mode propagation between transducers 102 and 104, the number of segments in each transducer, manufacturing tolerances of the segments, manufacturing tolerance of the thickness of the membrane and variation in that thickness, and many other factors. This situation is similar to the bandwidth considerations for SAW devices, and the tuning of the devices for particular bandwidths is known and will not be covered in detail here.

The noise of the current invention is limited by the insertion loss of the transducer and the inherent noise of the amplification medium. Because the amplification of medium noise should be only the thermal limit, the noise will be dominated by the insertion loss of the signal transducer. This is an improvement over the SAW devices, in which the signal must suffer the insertion loss of the signal transducer, the propagation loss in the device, and the insertion loss of the signal out transducer. For example, if we take the insertion loss of both a SAW transducer and a plate wave transducer to be −3 dB, then the noise power introduced by the SAW device will be 2 times the noise introduced by the plate wave parametric amplifier. A similar argument holds for the filter/amplifier/mixer.

The parametric amplifier described herein is resilient against changes in temperature and environmental radiation. The device will function down to zero Kelvin and at temperatures of many hundreds of degrees C., at which point components may melt or flow, and adhesion between layers may become unreliable. Radiation should have little or no deleterious effect until the plates become physically damaged. Finally, the device as practiced according to the invention is higher performance, and lower cost compared to currently available discrete components.

The transducers disclosed herein may be batch fabricated lithographically on a suitable substrate such as Si. When dividing the substrate into individual dies, it may be desirable to include more than one transducer on each die. It may further be desirable to pattern and fabricate support features such and resistors and capacitors, vias, active circuitry, and bonding pads, on each die.

Further objects and advantages of the invention include:

1. Ultra-low noise amplification

2. High power amplification

3. High Q resonant oscillation

4. Bandpass filtering

5. Variable-bandpass filtering

6. Multiple-bandpass filtering

7. Frequency mixing

8. Combinations of the above functions, including amplification and filtering in one device, amplification, filtering and mixing in one device, etc.

9. Combinations of all the above on a single die, to form various aspects of receiver and transmitter function that are currently done on a variety of separate devices.

While the invention has been particularly described and illustrated with reference to a preferred embodiment, it will be understood by those skilled in the art that changes in the description and illustrations may be made with respect to form and detail without departing from the spirit and scope of the invention. Accordingly, the present invention is to be considered as encompassing all modifications and variations coming within the scope defined by the following claims.

We claim:

1. A transducer comprising:
a first set of input electrodes;
a second set of output electrodes;
a first piezoelectric film, which generates a wave at a selected frequency in response to excitation by said first set of input electrodes;
a second piezoelectric film which delivers the wave to said second set of output electrodes;
a mechanically elastic material with transverse plate modes coupled mechanically to said first and second piezoelectric films; and
a pump transducer affixed to the mechanically elastic material.

2. The transducer of claim 1, wherein the first piezoelectric film and the second piezoelectric film are contiguously formed by a single monolithic piezoelectric film.

3. The transducer of claim 1, wherein the mechanically elastic material is chosen from the group consisting of plastic, silicon, glass, aluminum, nickel, tungsten, silicon nitride, quartz, germanium, gallium arsenide, zinc oxide and aluminum nitride.

4. The transducer of claim 1, wherein the piezoelectric films are chosen from the group consisting of zinc oxide, aluminum nitride, lead zirconium titanate, lithium niobate and lithium tantalate.

5. The transducer of claim 1, wherein the mechanically elastic material is patterned to create spatial modulation of its mechanical properties.

6. The transducer of claim 1, in which the first and second sets of electrodes have interdigitated fingers spaced by one-half of the selected frequency.

7. The transducer of claim 1, in which the first set of input electrodes, the second set of output electrodes and the pump transducer are oriented to produce a frequency up-converted output signal at the second set of output electrodes.

8. The transducer of claim 1, in which the first set of input electrodes, the second set of output electrodes and the pump transducer are oriented to produce a frequency down-converted output signal at the second set of output electrodes.

9. The transducer of claim 1, in which the first set of input electrodes, the second set of output electrodes and the pump transducer are oriented to produce an amplified output signal at the second set of output electrodes.

10. The transducer of claim 1, in which the first set of input electrodes, the second set of output electrodes and the pump transducer are oriented to produce an attenuated output signal at the second set of output electrodes.

11. The transducer of claim 1, further comprising one or more wave dampers.

12. The transducer of claim 1, further comprising one or more wave reflectors.

13. The transducer of claim 1, in which the first set of input electrodes, the second set of output electrodes and the pump transducer are oriented to produce a frequency-filtered output signal at the second set of output electrodes.

14. The transducer of claim 13, in which the pump wave amplitude is variable, in order to select a filter bandpass frequency width.

15. A transducer comprising:
a plurality of input electrodes;
a plurality of output electrodes;
a first piezoelectric film, which generates a wave in response to excitation by said input electrodes;
a second piezoelectric film which delivers the wave to said output electrodes;
a mechanically elastic material with transverse plate modes coupled mechanically to said first and second piezoelectric films; and
a pump transducer affixed to the mechanically elastic material.

16. The transducer of claim 15, wherein the first piezoelectric film and the second piezoelectric film are contiguously formed by a single monolithic piezoelectric film.

17. The transducer of claim 15, wherein the mechanically elastic material is chosen from the group consisting of plastic, silicon, glass, aluminum, nickel, tungsten, silicon nitride, zinc oxide, and aluminum nitride.

18. The transducer of claim 15, wherein the piezoelectric films are chosen from the group consisting of zinc oxide, aluminum nitride, lithium niobate and lithium tantalate.

19. The transducer of claim 15, wherein the mechanically elastic material is patterned to create spatial modulation of its mechanical properties.

20. The transducer of claim 15, in which the input and the output electrodes have interdigitated fingers spaced by one-half of the selected frequency.

21. The transducer of claim 15, in which the input electrodes, the output electrodes and the pump transducer are oriented to produce a frequency up-converted output signal at the second set of output electrodes.

22. The transducer of claim 15, in which the input electrodes, the output electrodes and the pump transducer are oriented to produce a frequency down-converted output signal at the second set of output electrodes.

23. The transducer of claim 15, in which the input electrodes, the output electrodes and the pump transducer are oriented to produce an amplified output signal at the second set of output electrodes.

24. The transducer of claim 15, in which the input electrodes, the output electrodes and the pump transducer are oriented to produce an attenuated output signal at the second set of output electrodes.

25. The transducer of claim 15, in which the input electrodes, the output electrodes and the pump transducer are oriented to produce a frequency-filtered output signal at the second set of output electrodes.

26. The transducer of claim 15, further comprising one or more wave dampers.

27. The transducer of claim 15, further comprising one or more wave reflectors.

28. A substrate for photolithographic processing, wherein each die in the substrate comprises one or more transducers, each transducer further comprising:
one or more input electrodes;
one or more output electrodes;
a first piezoelectric film, which generates a wave in response to excitation by said input electrodes;
a second piezoelectric film which delivers the wave to said output electrodes;
a mechanically elastic material with transverse plate modes coupled mechanically to said first and second piezoelectric films; and
a pump transducer affixed to the mechanically elastic material.

29. The substrate of claim 28, wherein each die further comprises support electronics for the transducers.

30. The substrate of claim 28, wherein each die comprises a plurality of transducers from the group consisting of amplifiers, bandpass filters, variable bandpass filters, oscillators, up-converters and down-converters.

31. A transducer comprising:
a set of output electrodes;
a piezoelectric film, which generates a response at a selected frequency to a propagating plate wave;
a pump transducer affixed to the mechanically elastic material.

32. The transducer of claim 31, wherein a mechanically elastic material with transverse plate modes is coupled mechanically to said output electrodes and pump transducer.

33. The transducer of claim 31, wherein the mechanically elastic material is chosen from the group consisting of plastic, silicon, glass, aluminum, nickel, tungsten, silicon nitride, zinc oxide and aluminum nitride.

34. The transducer of claim 31, wherein the piezoelectric films are chosen from the group consisting of zinc oxide, aluminum nitride, lead zirconium titanate, lithium niobate and lithium tantalate.

35. The transducer of claim 31, wherein the mechanically elastic material is patterned to create spatial modulation of its mechanical properties.

36. The transducer of claim 31, in which the sets of electrodes have interdigitated fingers spaced by one-half of the selected frequency.

37. The transducer of claim 31, in which the set of output electrodes and the pump transducer are oriented to produce an output signal at the output electrodes, forming an oscillator.

38. The transducer of claim 31, further comprising one or more wave reflectors
